(19) United States
(12) Patent Application Publication
(10) Pub. No.: US 2019/0172841 A1
(43) Pub. Date: Jun. 6, 2019

(54) SEMICONDUCTOR INTEGRATED CIRCUIT DEVICE

(71) Applicant: SOCIONEXT INC., Kanagawa (JP)

(72) Inventor: Keisuke KISHISHITA, Yokohama-shi (JP)

(21) Appl. No.: 16/269,360

(22) Filed: Feb. 6, 2019

Related U.S. Application Data
(63) Continuation of application No. PCT/JP2017/026298, filed on Jul. 20, 2017.

(30) Foreign Application Priority Data
Aug. 8, 2016 (JP) 2016-155878

(51) Int. Cl. H01L 27/118; H01L 27/02

(52) U.S. Cl. CPC H01L 27/11807; H01L 27/0207; H01L 2027/11861; H01L 2027/11864; H01L 2027/11857; H01L 2027/11812; H01L 2027/11835

(57) ABSTRACT

Provided is a semiconductor integrated circuit device including a nanowire field effect transistor (FET) and having a layout configuration effective for making manufacturing the device easy. In a standard cell including nanowire FETs connected in series through an intermediate node used only for mutual connection, the nanowire FETs include first, second, and third pads, Na nanowires extending in an X direction between the first and second pads to connect the first and second pads together, and Nb nanowires extending in the X direction between the second and third pads to connect the second and third pads together.

### CROSS-REFERENCE TO RELATED APPLICATIONS

This is a continuation of International Application No. PCT/JP2017/26298 filed on Jul. 20, 2017, which claims priority to Japanese Patent Application No. 2016-155878 filed on Aug. 8, 2016. The entire disclosures of these applications are incorporated by reference herein.

### BACKGROUND

The present disclosure relates to a semiconductor integrated circuit device including a standard cell including a nanowire field effect transistor (FET).

A standard cell design has been known as a method of forming a semiconductor integrated circuit on a semiconductor substrate. The standard cell design refers to a method of designing a large-scale integrated circuit (LSI) chip by providing in advance, as standard cells, unit logic elements having particular logical functions (for example, an inverter, a latch, a flip-flop, and a full adder), laying out those standard cells on a semiconductor substrate, and connecting those standard cells together through an interconnect.

Reducing a gate length (scaling) of transistors that are a basic element of the LSI have achieved more integrated transistors, reduced an operating voltage, and improved an operating rate. However, recently, off-current has been increased due to excessive scaling, and power has been consumed more and more due to the increase in off-current, which are problems. In order to solve such problems, three-dimensional transistors having a three-dimensional structure to which a change is made from a conventional two-dimensional structure have been actively researched. As one technique, nanowire FETs draw attention.

Examples of a method for manufacturing nanowire FETs are disclosed in S. Bangsaruntip, et al. “High performance and highly uniform gate-all-around silicon nanowire MOSFETs with wire size dependent scaling”, Electron Devices Meeting (IEDM), 2009 IEEE International and Isaac Laucer, et al. “Si Nanowire CMOS Fabricated with Minimal Deviation from RMG Fin FET Technology Showing Record Performance”, 2015 Symposium on VLSI Technology Digest of Technical Papers.

### SUMMARY

So far, neither a structure of a standard cell with a nanowire FET nor a layout of a semiconductor integrated circuit device including such a nanowire FET has been specifically studied.

The present disclosure relates to a semiconductor integrated circuit device including a nanowire FET, and provides a layout configuration effective for making manufacturing the device easy.

According to a first aspect of the present disclosure, a semiconductor integrated circuit includes a standard cell including first and second transistors that are nanowire field effect transistors (FETs), the first and second transistors being connected in series through a connection node used only for mutual connection. The first and second transistors include: a first pad; Na (Na is an integer of one or more) first nanowires each having a first end that is connected to the first pad, each extending in a first direction from the first end, and each having a lower surface above a lower surface of the first pad; a first gate electrode surrounding peripheries of the first nanowires within predetermined ranges of the first nanowires in the first direction; a second pad connected to second ends of the first nanowires; Nb (Nb is an integer of one or more) second nanowires each having a first end that is connected to the second pad, each extending in the first direction from the first end, and each having a lower surface above a lower surface of the second pad; a second gate electrode surrounding peripheries of the second nanowires within predetermined ranges of the second nanowires in the first direction; and a third pad connected to second ends of the second nanowires.

In accordance with this aspect, the second pad is provided between the first and second nanowires each constituting the connection node used only for connection between the first and second transistors, and the first and second nanowires are connected to this second pad. This configuration allows the second pad to support the first and second nanowires, and can improve the structural strength of the nanowire FETs. Consequently, process-induced variations in the semiconductor integrated circuit device can be reduced, and yield and reliability can be improved.

According to a second aspect of the present disclosure, a semiconductor integrated circuit includes: a standard cell including first and second transistors that are nanowire field effect transistors (FETs). The first and second transistors include: a first pad; Na (Na is an integer of one or more) first nanowires each having a first end that is connected to the first pad, each extending in a first direction from the first end, and each having a lower surface above a lower surface of the first pad; a first gate electrode surrounding peripheries of the first nanowires within predetermined ranges of the first nanowires in the first direction; a second pad connected to second ends of the first nanowires; Nb (Nb is an integer of one or more) second nanowires each having a first end that is connected to the second pad, each extending in the first direction from the first end, and each having a lower surface above a lower surface of the second pad; a second gate electrode surrounding peripheries of the second nanowires within predetermined ranges of the second nanowires in the first direction; and a third pad connected to second ends of the second nanowires. The second pad is not connected to any interconnect other than the first and second nanowires.

In accordance with this aspect, the second pad that is not connected to any interconnect other than the first and second nanowires is provided between the first nanowires forming part of the first transistor and the second nanowires forming part of the second transistor. In other words, the second pad that is not required to allow the circuit to function is provided. Provision of such a second pad allows the first and second nanowires to be supported, and can improve the structural strength of the nanowire FETs. Consequently, process-induced variations in the semiconductor integrated circuit device can be reduced, and yield and reliability can be improved.

According to a third aspect of the present disclosure, a semiconductor integrated circuit includes: a standard cell that is a NAND gate or a NOR gate having a serial portion including M (M is an integer of two or more) nanowire field effect transistors (FETs). The M nanowire FETs include: M+1 pads arranged at a predetermined pitch in a first direction; M groups of nanowires each including L (L is an integer of 1 or more) nanowires that are each provided between adjacent ones of the pads, extend in the first direction to connect the adjacent ones of the pads together, and each have a lower surface above lower surfaces of the pads; and M gate electrodes surrounding peripheries of the associated nanowires within predetermined ranges of the associated nanowires in the first direction.

In accordance with this aspect, in the serial portion of the standard cell that is the NAND gate or the NOR gate, the pads are provided between the adjacent nanowire FETs. Provision of such pads allows the nanowires provided between the adjacent pads to be supported, and can improve the structural strength of the nanowire FETs. Consequently, process-induced variations in the semiconductor integrated circuit device can be reduced, and yield and reliability can be improved.

The present disclosure makes it easy to manufacture a semiconductor integrated circuit device including a nanowire FET, can reduce process-induced variations in the semiconductor integrated circuit device, and can improve yield.

### BRIEF DESCRIPTION OF THE DRAWINGS

FIG. 1 is a plan view of a configuration example of a standard cell including nanowire field effect transistors (FETs) according to a first embodiment;

FIG. 2 is a circuit diagram of the standard cell of FIG. 1;

FIG. 3 is a cross-sectional view of the standard cell of FIG. 1;

FIG. 4 is a cross-sectional view of the standard cell of FIG. 1;

FIG. 5 is a plan view of another configuration example of the standard cell according to the first embodiment;

FIG. 6 is a circuit diagram of the standard cell of FIG. 5;

FIG. 7 is a plan view of a configuration example of a standard cell including nanowire FETs according to a second embodiment;

FIG. 8 is a circuit diagram of the standard cell of FIG. 7;

FIG. 9 is a plan view of another configuration example of the standard cell according to the second embodiment;

FIG. 10 is a plan view of still another configuration example of the standard cell according to the second embodiment;

FIG. 11 is a plan view of yet another configuration example of the standard cell according to the second embodiment;

FIG. 12 is a plan view of a further configuration example of the standard cell according to the second embodiment;

FIG. 13 is a plan view of a further configuration example of the standard cell according to the second embodiment;

FIG. 14 is a plan view of a further configuration example of the standard cell according to the second embodiment;

FIG. 15 shows a variation of the layout configuration of the standard cell of FIG. 1;

FIG. 16 schematically illustrates a basic configuration for the nanowire FET; and

FIG. 17 schematically illustrates a basic configuration for the nanowire FET.

### DETAILED DESCRIPTION

Embodiments will be described with reference to the drawings. In the following description of the embodiment, it is assumed that a semiconductor integrated circuit device includes a plurality of standard cells, at least some of which include a nanowire field effect transistor (FET).

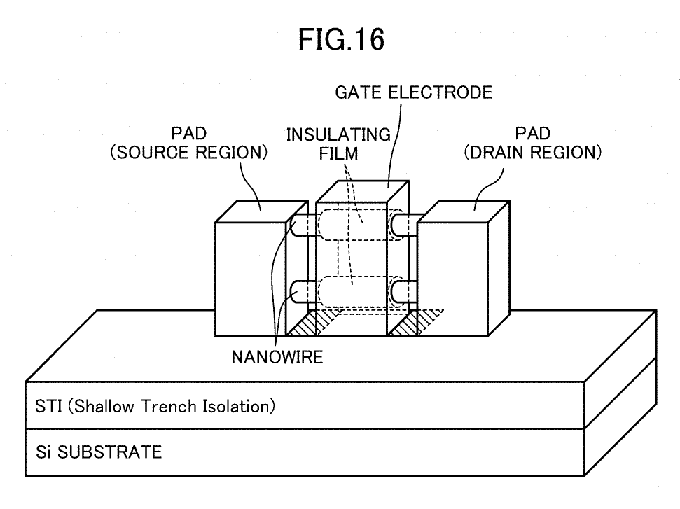

FIG. 16 is a schematic diagram of a basic structure example of the nanowire FET (also referred to as a nanowire gate all around (GAA) FET). The nanowire FET is an FET including thin wires (nanowires) through each of which a current flows. The nanowires are made of, e.g., silicon. As illustrated in FIG. 16, the nanowires are formed so as to extend horizontally above a substrate, i.e., extend parallel to the substrate, and each have both ends respectively connected to elements serving as source and drain regions of the nanowire FET. In this specification, in a nanowire FET, elements connected to both ends of a nanowire and serving as source and drain regions of the nanowire FET are each called a pad. In FIG. 16, a shallow trench isolation (STI) is formed on a Si substrate. However, the Si substrate is exposed in an (hatched) area under the nanowire. The hatched area may actually be covered with, e.g., a thermal oxide film. In FIG. 16, such a film is omitted for the sake of simplicity.

The nanowire is surrounded by a gate electrode comprised of, e.g., polysilicon via an insulating film such as a silicon oxide film. The pads and the gate electrode are formed on the substrate surface. With this configuration, all of upper, lower, and both side portions of a channel region of the nanowire are surrounded by the gate electrode, and thus, the electric field is evenly applied to the channel region, thus improving switching characteristics of the FET.

Although at least portions of the pads connected to the nanowire serve as the source/drain regions, portions of the pads below the portions connected to the nanowire do not necessarily serve as the source/drain regions. Portions of the nanowire (portions thereof not surrounded by the gate electrode) may serve as the source/drain regions.

In FIG. 16, two nanowires are arranged in the vertical direction, i.e., a direction perpendicular to the substrate. However, the number of the nanowires arranged in the vertical direction is not limited to two. Alternatively, one, three, or more nanowires may be arranged in the vertical direction. In FIG. 16, the upper end of the uppermost nanowire is at the same height as the upper end of the pad. However, the upper ends of these components do not necessarily have to be at the height, and the upper ends of the pads may be situated above the upper end of the uppermost nanowire.

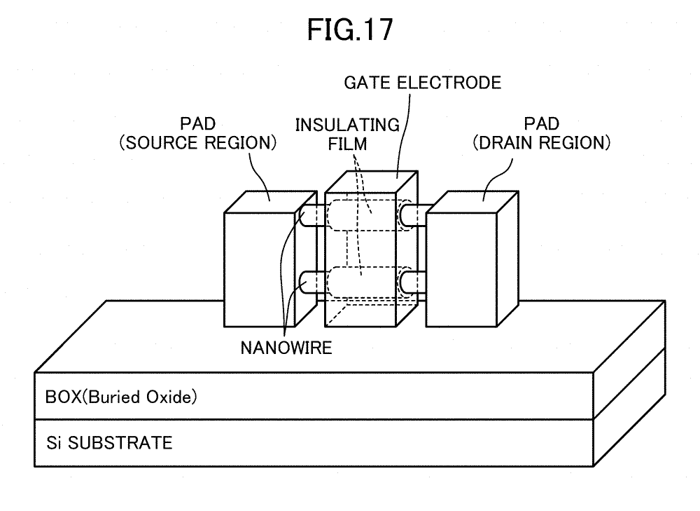

As shown in FIG. 17, in some cases, a buried oxide (BOX) is formed on the upper surface of the substrate, and the nanowire FET is formed on the BOX.

### First Embodiment

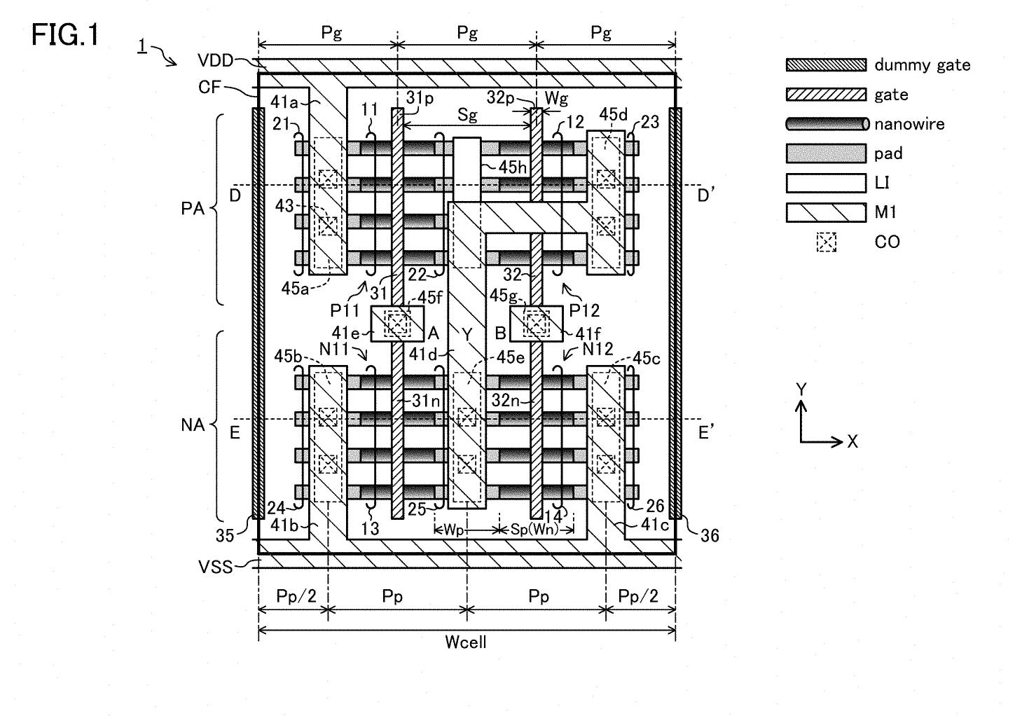

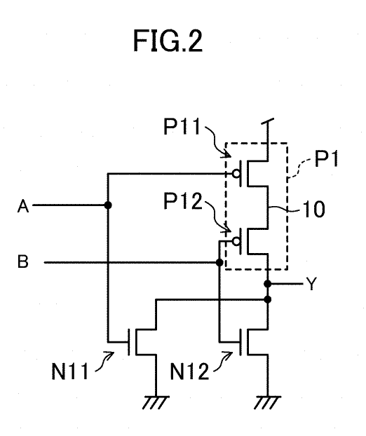

FIG. 1 is a plan view of a layout configuration example of a standard cell included in a semiconductor integrated circuit device according to a first embodiment. The standard cell 1 shown in FIG. 1 constitutes a 2-input NOR gate shown in the circuit diagram of FIG. 2 using nanowire FETs. In FIG. 1, the lateral direction on the paper is an X direction (corresponding to a first direction), and the longitudinal direction on the paper is a Y direction (corresponding to a second direction).

The standard cell 1 shown in FIG. 1 includes four nanowire FETs. That is to say, in the standard cell 1, a p-type transistor region PA and an-n-type transistor region NA are arranged in the Y direction, the p-type transistor region PA is provided with p-type nanowire FETs P11 and P12, and the n-type transistor region NA is provided with n-type nanowire FETs N11 and N12. As shown in the circuit diagram of FIG. 2, the nanowire FET P11 as a first transistor and the nanowire FET P12 as a second transistor are connected in series, and the nanowire FETs N11 and N12 are connected in parallel. In the standard cell 1 shown in FIG. 1, the nanowire FETs P11 and P12 connected in series constitute a serial portion P1.

The nanowire FETs P11, P12, N11, and N12 include a group of a plurality of parallelly arranged nanowires 11, a group of a plurality of parallelly arranged nanowires 12, a group of a plurality of parallelly arranged nanowires 13, and a group of a plurality of parallelly arranged nanowires 14, respectively. The nanowires 11, 12, 13, 14 extend in the X direction. Here, the groups of nanowires 11, 12, 13, 14 each include four nanowires arranged in the Y direction. As will be described below, the groups of nanowires 11, 12, 13, 14 further each include two nanowires arranged in the vertical direction, i.e., the direction perpendicular to the substrate, and each include eight nanowires in total. Each of the nanowires 11, 12, 13, 14 has a cylindrical shape, extends horizontally above the substrate, i.e., extends parallel to the substrate, and is comprised of, e.g., silicon. The standard cell 1 is provided with pads 21, 22, . . . , 26 each connected to associated ones of the nanowires 11, 12, 13, 14. P-type impurities are introduced into at least portions of the pads 21, 22, 23 connected to the associated nanowires 11, 12 and serving as source/drain regions of the nanowire FETs P11 and P12. N-type impurities are introduced into at least portions of the pads 24, 25, 26 connected to the associated nanowires 13, 14 and serving as source/drain regions of the nanowire FETs N11 and N12.

Here, the groups of the pads 21, 22, 23, 24, 25, 26 each include four pads separately arranged in the Y direction. The pads 21 are each connected to an associated one of the four nanowires 11 arranged in the Y direction. The pads 22 are each connected to an associated one of the four nanowires 11 arranged in the Y direction, and are each connected to an associated one of the four nanowires 12 arranged in the Y direction. The pads 23 are each connected to an associated one of the four nanowires 12 arranged in the Y direction. The pads 24 are each connected to an associated one of the four nanowires 13 arranged in the Y direction. The pads 25 are each connected to an associated one of the four nanowires 13 arranged in the Y direction, and are each connected to an associated one of the four nanowires 14 arranged in the Y direction. The pads 26 are each connected to an associated one of the four nanowires 14 arranged in the Y direction.

The nanowire FETs P11 and P12 connected together in series share the pads 22. That is to say, the nanowire FET P11 includes the pads 21 as first pads and the pads 22 as second pads. These pads 21, 22 are connected to the associated nanowires 11 as first nanowires. Similarly, the nanowire FET P12 includes the pads 22 and the pads 23 as third pads. These pads 22, 23 are connected to the associated nanowires 12 as second nanowires. The nanowire FETs N11 and N12 connected together in parallel share the pads 25. That is to say, the nanowire FET N11 includes the pads 24, 25 connected to the associated nanowires 13, and the nanowire FET N12 includes the pads 25, 26 connected to the associated nanowires 14.

The standard cell 1 is provided with two gate lines 31 and 32 which extend linearly along the Y direction. The gate line 31 is comprised of, as the first gate electrodes, a gate electrode 31p of the nanowire FET P11 and a gate electrode 31n of the nanowire FET N11, which are integrally formed with each other, and surrounds peripheries of the nanowires 11, 13 within predetermined ranges of the nanowires 11, 13 in the X direction. The gate line 32 is comprised of, as the second gate electrodes, a gate electrode 32p of the nanowire FET P12 and a gate electrode 32n of the nanowire FET N12, which are integrally formed with each other, and surrounds peripheries of the nanowires 12, 14 within predetermined ranges of the nanowires 12, 14 in the X direction. Lateral sides of a cell frame CF of the standard cell 1 are respectively provided with dummy gate lines 35 and 36 extending along the Y direction.

A metal interconnect layer M1 is formed above the nanowire FETs P11, P12, N11, and N12. The metal interconnect layer M1 includes an interconnect VDD disposed on the upper side of the cell frame CF and supplying a power supply potential, and an interconnect VSS disposed on the lower side of the cell frame CF and supplying a ground potential. The metal interconnect layer M1 further includes interconnects 41a, 41b, . . . , 41f. The interconnect 41a is formed so as to extend downward from the interconnect VDD along the Y direction, and is connected to the pads 21 through a local interconnect 45a. The interconnect 41b is formed so as to extend upward from the interconnect VSS along the Y direction, and is connected to the pads 24 through a local interconnect 45b. The interconnect 41c is formed so as to extend upward from the interconnect VSS along the Y direction, and is connected to the pads 26 through a local interconnect 45c. The interconnect 41d connects the pads 23, 25 together, and is connected to the pads 23 through a local interconnect 45d, and is connected to the pads 25 through a local interconnect 45e. The interconnect 41e is connected to the gate line 31 through a local interconnect 45f. The interconnect 41f is connected to the gate line 32 through a local interconnect 45g. The interconnects 41d, 41e, and 41f respectively correspond to an output Y, an input A, and an input B in the 2-input NOR circuit. A local interconnect 45h is disposed on the pads 22. Although the local interconnect 45h is connected to the pads 22, it is not connected to any interconnect of the metal interconnect layer M1.

The metallic interconnects 41a to 41f are each connected to an associated one or ones of the pads 21, 23, 24, 25, 26 and the gate lines 31 and 32 through associated ones of the local interconnects 45a, 45b, 45c, 45d, 45e, 45f, and 45g and contacts 43. Alternatively, the metallic interconnects may be connected to the pads and the gate lines only through the local interconnects, not through the contacts, or may be connected to the pads and the gate lines only through the contacts, not through the local interconnects.

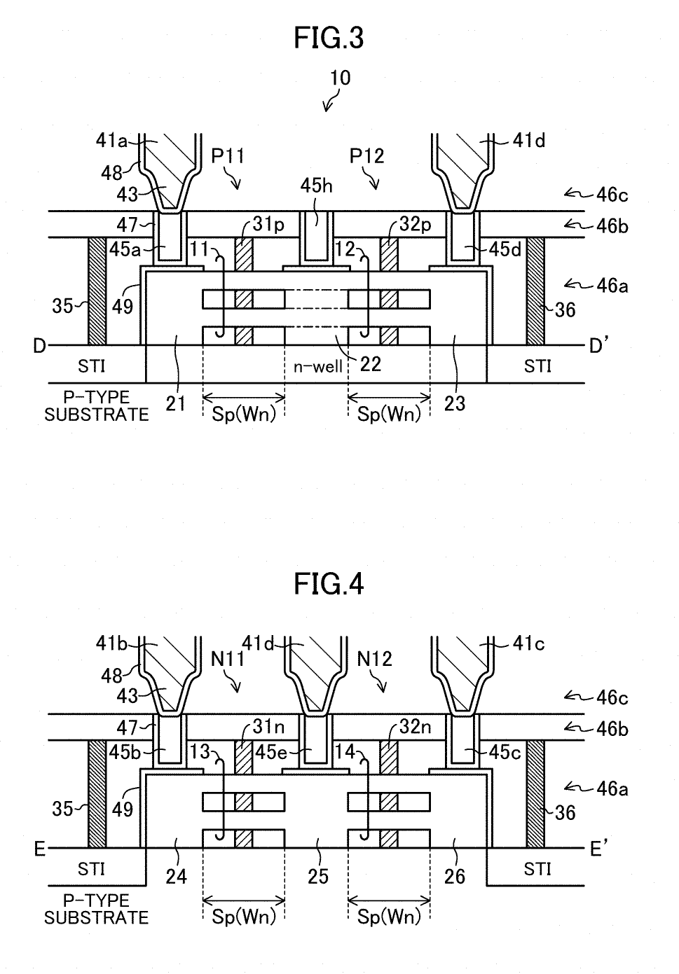

FIG. 3 is a cross-sectional view taken along line D-D′ of the layout configuration of FIG. 1, and FIG. 4 is a cross-sectional view taken along line E-E′ of the layout configuration of FIG. 1. As shown in FIGS. 3 and 4, the interconnects 41a to 41f of the metal interconnect layer M1 are respectively connected to the local interconnects 45a to 45g through contacts 43.

The contacts 43 are formed together with the interconnects 41a to 41f of the metal interconnect layer M1 using a dual-damascene process. The contacts 43 may be formed separately from the interconnects 41a to 41f of the metal interconnect layer M1. The interconnects 41a to 41f of the metal interconnect layer M1 are made of, e.g., Cu, and have a surface on which a barrier metal 48 including, e.g., tantalum or tantalum nitride is formed. The local interconnects 45a to 45h are made of, e.g., tungsten, and have a surface on which a glue film 47 including, e.g., titanium or titanium nitride is formed. The local interconnects 45a to 45h may be made of cobalt. In this case, the glue film 47 may be omitted. The pads 21 to 26 have a surface on which a silicide film 49 made of, e.g., nickel or cobalt is formed.

Interlayer insulating films 46a and 46b are each, e.g., a silicon oxide film. An interlayer insulating film 46c is a low dielectric constant film such as SiOC or a porous film. The interlayer insulating film 46c may have a multilayer structure including two or more layers.

The gate electrodes 31p, 31n, 32p, and 32n are made of, e.g., polysilicon. The gate electrodes 31p, 31n, 32p, and 32n may be made of a material including a metal such as titanium nitride. A gate insulating film is, e.g., a silicon oxide film, and is formed by, e.g., thermal oxidation. The gate insulating film may be formed of an oxide of hafnium, zirconium, lanthanum, yttrium, aluminum, titanium, or tantalum.

As can be seen from the cross-sectional views of FIGS. 3 and 4, the lower surfaces of the pads 21, 22, . . . , 26 are below those of the nanowires 11, 12, 13, 14. The upper surfaces of the groups of the nanowires 11, 12, 13, 14 are at the same height as those of the pads 21, 22, . . . , 26. The gate electrodes 31p, 32p, 31n, and 32n surround peripheries of the nanowires 11, 12, 13, 14, respectively. That is to say, all of upper, lower, and both side surfaces of a channel region of each of the nanowires 11, 12, 13, 14 are surrounded by an associated one of the gate electrodes 31p, 32p, 31n, and 32n through the associated insulating film. The upper surfaces of the groups of the nanowires 11, 12, 13, 14 may be below the upper surfaces of the pads 21, 22, 23, 24, 25, 26. A buried oxide (BOX) may be formed on the upper surface of the substrate.

In the standard cell 1 of FIG. 1, the pads are arranged at an equal pitch Pp in the X direction. That is to say, the pads 21, 22, 23 are arranged in the p-type transistor region PA at the pitch Pp, and the pads 24, 25, 26 are arranged in the n-type transistor region NA at the pitch Pp. The pads in the p-type transistor region PA and the associated pads in the n-type transistor region NA have the same position in the X direction. That is to say, the pads 21 and the associated pads 24 have the same position in the X direction. Similarly, the pads 22 and the pads 25 have the same position in the X direction, and the pads 23 and the pads 26 have the same position in the X direction. Dimensions in the X direction of the pads, i.e., the pad widths Wp, are all equal, and the intervals between the adjacent pads in the X direction, i.e., the pad intervals Sp, are all equal. Therefore, the following relation is satisfied:

Pp=Wp+Sp

In each of the p-type transistor region PA and the n-type transistor region NA, the pads are connected together in the X direction through the associated nanowires. Consequently, the length Wn of each of the nanowires is equal to the pad interval Sp. That is to say, the following relation is satisfied:

Wn=Sp

The lengths Wn of the nanowires 11, 12, 13, 14 are all equal.

An interval between the cell frame CF and the center line of each of the pads 21, 23, 24, 26 closest to the cell frame CF is ½ of the pitch Pp between the pads. As a result, the dimension in the X direction of the standard cell 1, i.e., a cell width Wcell, is an integral multiple of the pitch Pp between the pads (in this embodiment, three times the pitch Pp).

In the standard cell 1 of FIG. 1, the gate lines (including the dummy gate lines) are arranged at an equal pitch Pg in the X direction. Dimensions in the X direction of the gate lines, i.e., the gate line widths Wg, are all equal, and the intervals between the gate lines in the X direction, i.e., the intervals Sg, are all equal. Therefore, the following relation is satisfied:

Pg=Wg+Sg

A pitch Pg between the gate lines is equal to the pitch Pp between the pads. That is to say, the following relation is satisfied:

Pp=Pg

The layout configuration of FIG. 1 has the following features.

In the p-type transistor region PA, the nanowire FETs P11 and P12 constituting the serial portion P1 are connected together through an intermediate node 10. This intermediate node 10 is a node used only for connection between the nanowire FETs P11 and P12. That is to say, elements, power supply interconnects, and signal interconnects other than the nanowire FETs P11 and P12 are not directly connected to the intermediate node 10. Consequently, there is no need to provide pads between the nanowire FETs P11 and P12 (see the dot and dash line of FIG. 3).

In the present embodiment, the pads 22 are provided at intermediate positions of the nanowires constituting the intermediate node 10, i.e., positions corresponding to portions of the nanowires between the gate electrodes 31p and 32p. The nanowires 11, 12 forming part of the nanowire FETs P11 and P12 are connected to the associated pads 22. This configuration can substantially prevent the nanowires within the standard cell from having different lengths. Further, the pads 22 can support the nanowires 11, 12, and improve the structural strength of the nanowire FETs. This can reduce process-induced variations in the semiconductor integrated circuit device including the standard cell according to the present embodiment, and can improve yield and reliability.

### Another Example

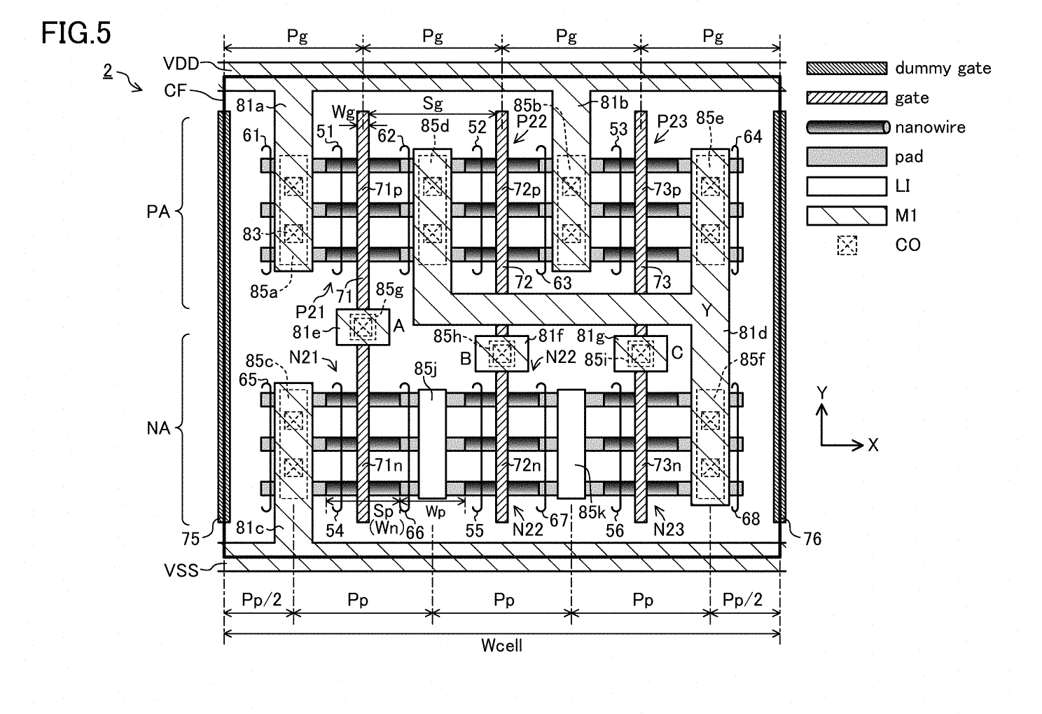

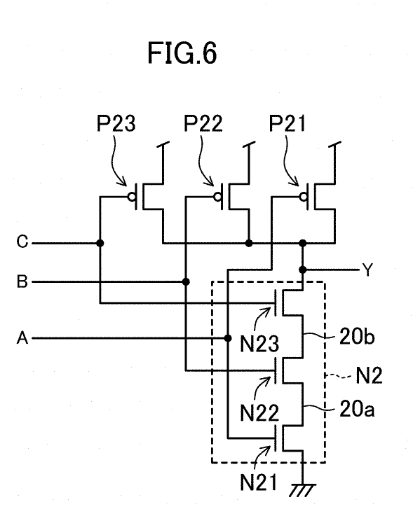

FIG. 5 is a plan view of a layout configuration example of the standard cell included in the semiconductor integrated circuit device according to the first embodiment. The standard cell 2 shown in FIG. 5 constitutes a three-input NAND gate shown in the circuit diagram of FIG. 6 using nanowire FETs. In FIG. 5, just like in FIG. 1, the lateral direction on the paper is the X direction (corresponding to the first direction), and the longitudinal direction on the paper is the Y direction (corresponding to the second direction). The cross-sectional structure of the standard cell is similar to that shown in FIGS. 3 and 4, and is not shown here.

The standard cell 2 shown in FIG. 5 includes six nanowire FETs. That is to say, the standard cell 2 includes the p-type transistor region PA and the n-type transistor region NA arranged in the Y direction. The p-type transistor region PA is provided with p-type nanowire FETs P21, P22, and P23, and the n-type transistor region NA is provided with n-type nanowire FETs N21, N22, and N23. As shown in the circuit diagram of FIG. 6, the nanowire FETs P21, P22, and P23 are connected in parallel, and the nanowire FETs N21, N22, and N23 are connected in series. In the standard cell 2 shown in FIG. 5, the nanowire FETs N21, N22, and N23 connected in series constitute a serial portion N2.

The nanowire FETs P21, P22, P23, N21, N22, and N23 include a group of a plurality of parallelly arranged nanowires 51, a group of a plurality of parallelly arranged nanowires 52, . . . , and a group of a plurality of parallelly arranged nanowires 56, respectively. The nanowires 51, 52, . . . , 56 extend in the X direction. Here, the groups of nanowires 51, 52, 53, 54, 55, 56 each include three nanowires arranged in the Y direction. The groups of nanowires 51, 52, 53, 54, 55, 56 further each include two nanowires arranged in the vertical direction, i.e., the direction perpendicular to the substrate. The groups of nanowires 51, 52, 53, 54, 55, 56 each include six nanowires in total. Each of the nanowires 51, 52, . . . , 56 has a cylindrical shape, extends horizontally above the substrate, i.e., extends parallel to the substrate, and is comprised of, e.g., silicon. The standard cell 2 is provided with pads 61, 62, . . . , 68 connected to associated ones of the nanowires 51, 52, . . . , 56. P-type impurities are introduced into at least portions of the pads 61, 62, 63, 64 connected to the nanowires 51, 52, 53 and serving as source/drain regions of the nanowire FETs P21, P22, and P23. N-type impurities are introduced into at least portions of the pads 65, 66, 67, 68 connected to the nanowires 54, 55, 56 and serving as source/drain regions of the nanowire FETs N21, N22, and N23.

Here, the groups of the pads 61, 62, 63, 64, 65, 66, 67, 68 each include three pads separately arranged in the Y direction. The separately arranged three pads 61 are each connected to an associated one of the three nanowires 51 arranged in the Y direction. The separately arranged three pads 62 are each connected to an associated one of the three nanowires 51 arranged in the Y direction, and are each connected to an associated one of the three nanowires 52 arranged in the Y direction. The separately arranged three pads 63 are each connected to an associated one of the three nanowires 52 arranged in the Y direction, and are each connected to an associated one of the three nanowires 53 arranged in the Y direction. The separately arranged three pads 64 are each connected to an associated one of the three nanowires 53 arranged in the Y direction. The separately arranged three pads 65 are each connected to an associated one of the three nanowires 54 arranged in the Y direction. The separately arranged three pads 66 are each connected to an associated one of the three nanowires 54 arranged in the Y direction, and are each connected to an associated one of the three nanowires 55 arranged in the Y direction. The separately arranged three pads 67 are each connected to an associated one of the three nanowires 55 arranged in the Y direction, and are each connected to an associated one of the three nanowires 56 arranged in the Y direction. The separately arranged three pads 68 are each connected to an associated one of the three nanowires 56 arranged in the Y direction.

The nanowire FETs P21 and P22 connected in parallel share the pads 62, and the nanowire FETs P22 and P23 connected in parallel share the pads 63. That is to say, the nanowire FET P21 includes the pads 61, 62 connected to the associated nanowires 51, the nanowire FET P22 includes the pads 62, 63 connected to the associated nanowires 52, and the nanowire FET P23 includes the pads 63, 64 connected to the associated nanowires 53. The nanowire FETs N21 and N22 connected in series share the pads 66, and the nanowire FETs N22 and N23 connected in series share the pads 67. That is to say, the nanowire FET N21 includes the pads 65, 66 connected to the associated nanowires 54, the nanowire FET N22 includes the pads 66, 67 connected to the associated nanowires 55, and the nanowire FET N23 includes the pads 67, 68 connected to the associated nanowires 56.

The standard cell 2 is provided with three gate lines 71, 72, and 73 extending in the Y direction. The gate line 71 is comprised of a gate electrode 71p of the nanowire FET P21 and a gate electrode 71n of the nanowire FET N21, which are integrally formed with each other, and surrounds peripheries of the nanowires 51, 54 within predetermined ranges of the nanowires 51, 54 in the X direction. The gate line 72 is comprised of a gate electrode 72p of the nanowire FET P22 and a gate electrode 72n of the nanowire FET N22, which are integrally formed with each other, and surrounds peripheries of the nanowires 52, 55 within predetermined ranges of the nanowires 52, 55 in the X direction. The gate line 73 is comprised of a gate electrode 73p of the nanowire FET P23 and a gate electrode 73n of the nanowire FET N23, which are integrally formed with each other, and surrounds peripheries of the nanowires 53, 56 within predetermined ranges of the nanowires 53, 56 in the X direction. Lateral sides of a cell frame CF of the standard cell 2 are respectively provided with dummy gate lines 75 and 76 extending in the Y direction.

The metal interconnect layer M1 is formed above the nanowire FETs P21, P22, P23, N21, N22, and N23. The metal interconnect layer M1 includes an interconnect VDD disposed on the upper side of the cell frame CF and supplying a power supply potential, and an interconnect VSS disposed on the lower side of the cell frame CF and supplying a ground potential. The metal interconnect layer M1 further includes interconnects 81a to 81g. The interconnect 81a is formed so as to extend downward from the interconnect VDD along the Y direction, and is connected to the pads 61 through a local interconnect 85a. The interconnect 81b is formed so as to extend downward from the interconnect VDD along the Y direction, and is connected to the pads 63 through a local interconnect 85b. The interconnect 81c is formed so as to extend upward from the interconnect VSS along the Y direction, and is connected to the pads 65 through a local interconnect 85c. The interconnect 81d connects the pads 62, 64, 68 together, and is connected to the pads 62 through a local interconnect 85d, is connected to the pads 64 through a local interconnect 85e, and is connected to the pads 68 through a local interconnect 85f. The interconnect 81e is connected to the gate line 71 through a local interconnect 85g. The interconnect 81f is connected to the gate line 72 through a local interconnect 85h. The interconnect 81g is connected to the gate line 73 through a local interconnect 85i. The interconnects 81d, 81e, 81f, and 81g respectively correspond to an output Y, an input A, an input B, and an input C in the three-input NAND circuit. A local interconnect 85j is disposed on the pads 66, and a local interconnect 85k is disposed on the pads 67. Although the local interconnect 85j is connected to the pads 66, it is not connected to any interconnect of the metal interconnect layer M1. Although the local interconnect 85k is connected to the pads 67, it is not connected to any interconnect of the metal interconnect layer M1.

The metallic interconnects 81a, 81b, 81c, 81d, 81e, 81f, and 81g are each connected to an associated one or ones of the pads 61, 62, 63, 64, 65, 68 and the gate lines 71, 72, and 73 through associated ones of the local interconnects 85a, 85b, 85c, 85d, 85e, 85f, 85g, 85h, and 85i and contacts 83. Alternatively, the metallic interconnects may be connected to the pads and the gate lines only through the local interconnects, not through the contacts, or may be connected to the pads and the gate lines only through the contacts, not through the local interconnects.

The cross-sectional structure of the standard cell 2 is similar to that of the standard cell 1. That is to say, the lower surfaces of the pads 61, 62, . . . , 68 are below the lower surfaces of the nanowires 51, 52, . . . , 56. The upper surfaces of the nanowires 51, 52, . . . , 56 are at the same height as the upper surfaces of the pads 61, 62, . . . , 68. The gate electrodes 71p, 72p, 73p, 71n, 72n, and 73n surround the peripheries of the nanowires 51, 52, . . . , 56. That is to say, all of upper, both side, and lower surfaces of the channel regions of the nanowires 51, 52, . . . , 56 are each surrounded by an associated one of the gate electrodes 71p, 72p, 73p, 71n, 72n, and 73n through an associated one of the insulating films. The upper surfaces of the nanowires 51, 52, . . . , 56 may be below the upper surfaces of the pads 61, 62, . . . , 68.

In the standard cell 2 of FIG. 5, the pads are arranged at an equal pitch Pp in the X direction. That is to say, the pads 61, 62, 63, 64 are arranged in the p-type transistor region PA at the pitch Pp, and the pads 65, 66, 67, 68 are arranged in the n-type transistor region NA at the pitch Pp. The pads in the p-type transistor region PA and the associated pads in the n-type transistor region NA have the same position in the X direction. That is to say, the pads 61 and the associated pads 65 have the same position in the X direction. Similarly, the pads 62 and the pads 66 have the same position in the X direction, the pads 63 and the associated pads 67 have the same position in the X direction, and the pads 64 and the associated pads 68 have the same position in the X direction. The widths Wp of the pads are all equal, and the pad intervals Sp in the X direction are all equal. Therefore, the following relation is satisfied:

Pp=Wp+Sp

In each of the p-type transistor region PA and the n-type transistor region NA, the pads are connected together in the X direction through the associated nanowires. Consequently, the length Wn of the nanowires is equal to the pad interval Sp. That is to say, the following relation is satisfied:

Wn=Sp

The lengths Wn of the nanowires 51, 52, . . . , 56 are all equal.

An interval between the cell frame CF and the center line of each of the pads 61, 64, 65, 68 closest to the cell frame CF is ½ of the pitch Pp between the pads. As a result, the cell width Wcell of the standard cell 2 is an integral multiple of the pitch Pp between the pads (in this embodiment, four times the pitch Pp).

In the standard cell 2 of FIG. 5, the gate lines (including the dummy gate lines) are arranged at an equal pitch Pg in the X direction. The widths Wg of the gate lines are all equal, and the pad intervals Sg in the X direction are all equal. Therefore, the following relation is satisfied:

Pg=Wg+Sg

A pitch Pg between the gate lines is equal to the pitch Pp between the pads. That is to say, the following relation is satisfied:

Pp=Pg

In the configuration of FIG. 5, among the nanowire FETs N21, N22, and N23 constituting the serial portion N2 in the n-type transistor region NA, the nanowire FETs N21 and N22 are connected together through an intermediate node 20a, and the nanowire FETs N22 and N23 are connected together through an intermediate node 20b. The intermediate node 20a is a node used only for connection between the nanowire FETs N21 and N22, and the intermediate node 20b is a node used only for connection between the nanowire FETs N22 and N23. That is to say, elements, power supply interconnects, and signal interconnects other than the nanowire FETs N21 and N22 are not directly connected to the intermediate node 20a. Similarly, elements, power supply interconnects, and signal interconnects other than the nanowire FETs N22 and N23 are not directly connected to the intermediate node 20b. Consequently, there is no need to provide pads between the nanowire FETs N21 and N22 and between the nanowire FETs N22 and N23.

In the configuration of FIG. 5, just like in the configuration of FIG. 1, the pads 66 are provided at intermediate positions of the nanowires constituting the intermediate node 20a, i.e., positions corresponding to portions of the nanowires between the gate electrodes 71n and 72n. Similarly, the pads 67 are provided at intermediate positions of the nanowires constituting the intermediate node 20b, i.e., positions corresponding to portions of the nanowires between the gate electrodes 72n and 73n. The nanowires 54, 55 forming part of the nanowire FETs N21 and N22 are connected to the associated pads 66. The nanowires 55, 56 forming part of the nanowire FETs N22 and N23 are connected to the associated pads 67.

This configuration can substantially prevent the nanowires within the standard cell from having different lengths. Further, the pads 66, 67 can support the nanowires 54, 55, 56, and improve structural strength of the nanowire FETs. This can reduce process-induced variations in the semiconductor integrated circuit device and can improve yield and reliability.

In the configuration of FIG. 5, in the standard cell of the three-input NAND gate of FIG. 6, M (M is an integer of 2 or more, M=3 in FIG. 5) nanowire FETs N21, N22, and N23 constituting the serial portion N2 include (M+1) groups of pads 65, 66, 67, 68 arranged at a predetermined pitch in the X direction, M groups of nanowires 54, 55, 56 each provided between adjacent ones of the groups of the pads, and M gate electrodes 71n, 72n, and 73n surrounding the peripheries of the groups of the nanowires. The M groups of the nanowires 54, 55, 56 each include a total of L (L is an integer of 1 or more, L=6 in FIG. 5) nanowires that extend in the X direction to connect the adjacent pads together and have a lower surface above the lower surfaces of the pads.

Although, in the configuration of FIG. 5, M is equal to 3 and L is equal to 6, the values M and L do not have to be 3 and 6, respectively. A serial portion of a NOR gate may have a similar configuration. The M groups of the nanowires 54, 55, and 56 may have the same length in the X direction.

### Second Embodiment

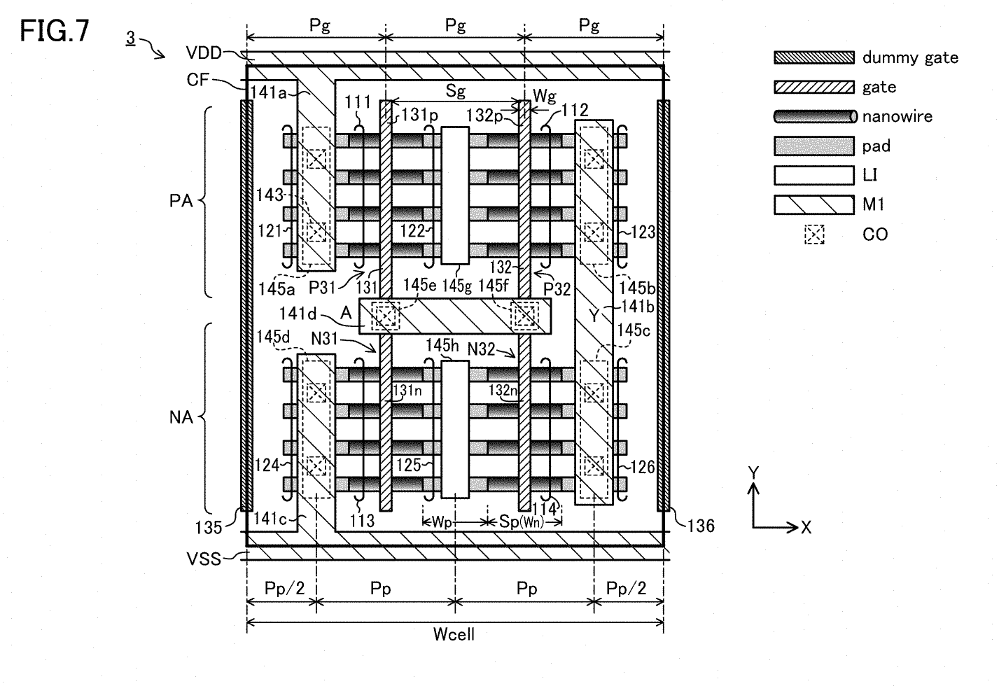

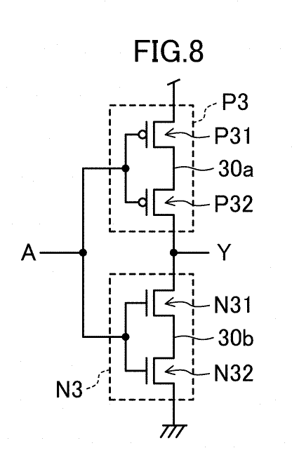

FIG. 7 is a plan view illustrating a layout configuration example of a standard cell included in a semiconductor integrated circuit device according to the embodiment. The standard cell 3 shown in FIG. 7 constitutes an inverter shown in the circuit diagram of FIG. 8 using nanowire FETs. In FIG. 7, just like in FIG. 1, the lateral direction on the paper is an X direction (corresponding to a first direction), and the longitudinal direction on the paper is a Y direction (corresponding to a second direction). The cross-sectional structure of the standard cell is similar to that shown in FIG. 3, and is not shown here.

The standard cell 3 shown in FIG. 7 includes four nanowire FETs. That is to say, in the standard cell 3, a p-type transistor region PA and an n-type transistor region NA are arranged in the Y direction, the p-type transistor region PA is provided with p-type nanowire FETs P31 and P32, and the n-type transistor region NA is provided with n-type nanowire FETs N31 and N32. As shown in the circuit diagram of FIG. 8, the nanowire FETs P31 and P32 are connected in series, and the nanowire FETs N31 and N32 are connected in series. In the standard cell 3 shown in FIG. 7, the nanowire FETs P31 and P32 connected in series constitute a serial portion P3, and the nanowire FETs N31 and N32 connected in series constitute a serial portion N3.

The nanowire FETs P31, P32, N31, and N32 include a group of a plurality of parallelly arranged nanowires 111, a group of a plurality of parallelly arranged nanowires 112, a group of a plurality of parallelly arranged nanowires 113, and a group of a plurality of parallelly arranged nanowires 114, respectively. The nanowires 111, 112, 113, 114 extend in the X direction. Here, the groups of nanowires 111, 112, 113, 114 each include four nanowires arranged in the Y direction. The groups of nanowires 111, 112, 113, 114 further each include two nanowires arranged in the vertical direction, i.e., the direction perpendicular to the substrate, and each include eight nanowires in total. Each of the nanowires 111, 112, 113, 114 has a cylindrical shape, extends horizontally above the substrate, i.e., parallel to the substrate, and is comprised of, e.g., silicon. The standard cell 3 is provided with pads 121, 122, . . . , 126 each connected to associated ones of the nanowires 111, 112, 113, 114. P-type impurities are introduced into at least portions of the pads 121, 122, 123 connected to the associated nanowires 111, 112 and serving as source/drain regions of the nanowire FETs P31 and P32. N-type impurities are introduced into at least portions of the pads 124, 125, 126 connected to the associated nanowires 113 and 114 and serving as source/drain regions of the nanowire FETs N31 and N32.

Here, the groups of the pads 121, 122, 123, 124, 125, 126 each include four pads separately arranged in the Y direction. The pads 121 are each connected to an associated one of the four nanowires 111 arranged in the Y direction. The separately arranged four pads 122 are each connected to an associated one of the four nanowires 111 arranged in the Y direction, and are each connected to an associated one of the four nanowires 112 arranged in the Y direction. The separately arranged four pads 123 are each connected to an associated one of the four nanowires 112 arranged in the Y direction. The separately arranged four pads 124 are each connected to an associated one of the four nanowires 113 arranged in the Y direction. The separately arranged four pads 125 are each connected to an associated one of the four nanowires 113 arranged in the Y direction, and are each connected to an associated one of the four nanowires 114 arranged in the Y direction. The separately arranged four pads 126 are each connected to an associated one of the four nanowires 114 arranged in the Y direction.

The nanowire FETs P31 and P32 connected in series share the pads 122, and the nanowire FETs N31 and N32 connected in series share the pads 125. That is to say, the nanowire FET P31 includes the pads 121 and 122 connected to the associated nanowires 111, and the nanowire FET P32 includes the pads 122 and 123 connected to the associated nanowires 112. The nanowire FET N31 includes the pads 124 and 125 connected to the associated nanowires 113, and the nanowire FET N32 includes the pads 125 and 126 connected to the associated nanowires 114.

The standard cell 3 is provided with two gate lines 131 and 132 which extend linearly along the Y direction. The gate line 131 is comprised of a gate electrode 131p of the nanowire FET P31 and a gate electrode 131n of the nanowire FET N31, which are integrally formed with each other, and surrounds peripheries of the nanowires 111, 113 within predetermined ranges of the nanowires 111, 113 in the X direction. The gate line 132 is comprised of a gate electrode 132p of the nanowire FET P32 and a gate electrode 132n of the nanowire FET N32, which are integrally formed with each other, and surrounds peripheries of the nanowires 112, 114 within predetermined ranges of the nanowires 112, 114 in the X direction. Lateral sides of a cell frame CF of the standard cell 3 are respectively provided with dummy gate lines 135 and 136 extending along the Y direction.

The metal interconnect layer M1 includes an interconnect VDD disposed on the upper side of the cell frame CF and supplying a power supply potential, and an interconnect VSS disposed on the lower side of the cell frame CF and supplying a ground potential. The metal interconnect layer M1 further includes interconnects 141a, 141b, 141c, and 141d. The interconnect 141a is formed so as to extend downward from the interconnect VDD along the Y direction, and is connected to the pads 121 through a local interconnect 145a. The interconnect 141b connects the pads 123 and 126 together, is connected to the pads 123 through a local interconnect 145b, and is connected to the pads 126 through a local interconnect 145c. The interconnect 141c is formed so as to extend upward from the interconnect VSS along the Y direction, and is connected to the pads 124 through a local interconnect 145d. The interconnect 141d connects the gate lines 131 and 132 together, is connected to the gate line 131 through a local interconnect 145e, and is connected to the gate line 132 through a local interconnect 145f. With this configuration, the same signal is input to the gate electrode 131p of the nanowire FET P31 and the gate electrode 132p of the nanowire FET P32. Similarly, the same signal is input to the gate electrode 131n of the nanowire FET N31 and the gate electrode 132n of the nanowire FET N32. The interconnects 141b and 141d respectively correspond to an output Y and an input A of the inverter constituted by the standard cell 3. A local interconnect 145g is disposed on the pads 122, and a local interconnect 145h is disposed on the pads 125. Although the local interconnect 145g is connected to the pads 122, it is not connected to any interconnect of the metal interconnect layer M1. Although the local interconnect 145h is connected to the pads 125, it is not connected to any interconnect of the metal interconnect layer M1.

The metallic interconnects 141a to 141d are each connected to an associated one or ones of the pads 121, 123, 124, 126 and the gate lines 131 and 132 through associated ones of the local interconnects 145a, 145b, 145c, 145d, 145e, and 145f and contacts 143. Alternatively, the metallic interconnects may be connected to the pads and the gate lines only through the local interconnects, not through the contacts, or may be connected to the pads and the gate lines only through the contacts, not through the local interconnects.

In the standard cell 3 of FIG. 7, just like in FIG. 1, the pads are arranged at the equal pitch Pp in the X direction. Dimensions in the X direction of the pads, i.e., the pad widths Wp, are all equal, and the intervals between the adjacent pads in the X direction, i.e., the pad intervals Sp, and the lengths Wn of the nanowires 111, 112, 113, 114 are all equal.

In the configuration of FIG. 7, in the p-type transistor region PA, the nanowire FETs P31 and P32 constituting the serial portion P3 are connected together through an intermediate node 30a. This intermediate node 30a is a node used only for connection between the nanowire FETs P31 and P32. That is to say, elements, power supply interconnects, and signal interconnects other than the nanowire FETs P31 and P32 are not directly connected to the intermediate node 30a. Consequently, there is no need to provide pads between the nanowire FETs P31 and P32. Similarly, in the n-type transistor region NA, the nanowire FETs N31 and N32 constituting the serial portion N3 are connected together through an intermediate node 30b. This intermediate node 30b is a node used only for connection between the nanowire FETs N31 and N32. That is to say, elements, power supply interconnects, and signal interconnects other than the nanowire FETs N31 and N32 are not directly connected to the intermediate node 30b. Consequently, there is no need to provide pads between the nanowire FETs N31 and N32.

In the present embodiment, the pads 122 are provided at intermediate positions of the nanowires constituting the intermediate node 30a, i.e., positions corresponding to portions of the nanowires between the gate electrodes 131p and 132p. The nanowires 111, 112 forming part of the nanowire FETs P31 and P32 are connected to the associated pads 122. This configuration can substantially prevent the nanowires within the standard cell from having different lengths. Further, the pads 122 can support the nanowires 111, 112, and improve the structural strength of the nanowire FETs. Similarly, the pads 125 are provided at intermediate positions of the nanowires constituting the intermediate node 30b, i.e., positions corresponding to portions of the nanowires between the gate electrodes 131n and 132n. The nanowires 113, 114 forming part of the nanowire FETs N31 and N32 are connected to the associated pads 125. This configuration can substantially prevent the nanowires within the standard cell having different lengths. Further, the pads 125 can support the nanowires 113, 114, and improve the structural strength of the nanowire FETs. This can reduce process-induced variations in the semiconductor integrated circuit device including the standard cell according to the present embodiment, and can improve yield and reliability.

Further, in the configuration of FIG. 7, in the p-type transistor region PA, the interconnect 141d is connected to the gate electrodes 131p and 132p of the nanowire FETs P31 and P32 constituting the serial portion P3, and the same input signal is given to these gate electrodes from the input A. The nanowire FETs P31 and P32 with the same input are thus connected in series, thus allowing the serial portion P3 to achieve driving capability weaker than that of the nanowire FET P31. Similarly, in the n-type transistor region NA, the interconnect 141d is connected to the gate electrodes 131n and 132n of the nanowire FETs N31 and N32 constituting the serial portion N3, and the same input signal is given to these gate electrodes from the input A. This allows the serial portion N3 to achieve driving capability weaker than that of the nanowire FET N31.

Although, in the configuration of FIG. 7, the number of the nanowires 111 constituting the nanowire FET P31 and the number of the nanowires 112 constituting the nanowire FET P32 are each eight, they are non-limiting examples, and may be each any number. For example, when the number of the nanowires 111 constituting the nanowire FET P31 and the number of the nanowires 112 constituting the nanowire FET P32 are each one, the configuration of FIG. 7 can provide a transistor having driving capability still weaker than that of a nanowire FET having one nanowire, i.e., the least number of nanowires. Further, the configuration of FIG. 7 allows the driving capability of the serial portion to be adjusted to a value unachievable by changing the number of the nanowires alone. For example, when the number of the nanowires 111 of the nanowire FET P31 and the number of the nanowires 112 of the nanowire FET P32 are both Nx (Nx is an odd number), the driving capability of the serial portion P3 can be set to be about ½ of that of the nanowire FET P31. The same statement applies to the serial portion N3.

Although, in the configuration of FIG. 7, the p-type transistor region PA and the n-type transistor region NA are respectively provided with the serial portions P3 and N3 where the transistors with the same input are connected in series, this is a non-limiting example, and either one of the regions may be provided with the serial portion P3 or N3. The number of the nanowire FETs with the same input connected in series and constituting the serial portion P3 or N3 is not limited to two, and three or more nanowire FETs with the same input may be connected in series. Further, the number of the nanowire FETs connected in series in the p-type transistor region PA may be different from that in the n-type transistor region NA.

### Another Example 1

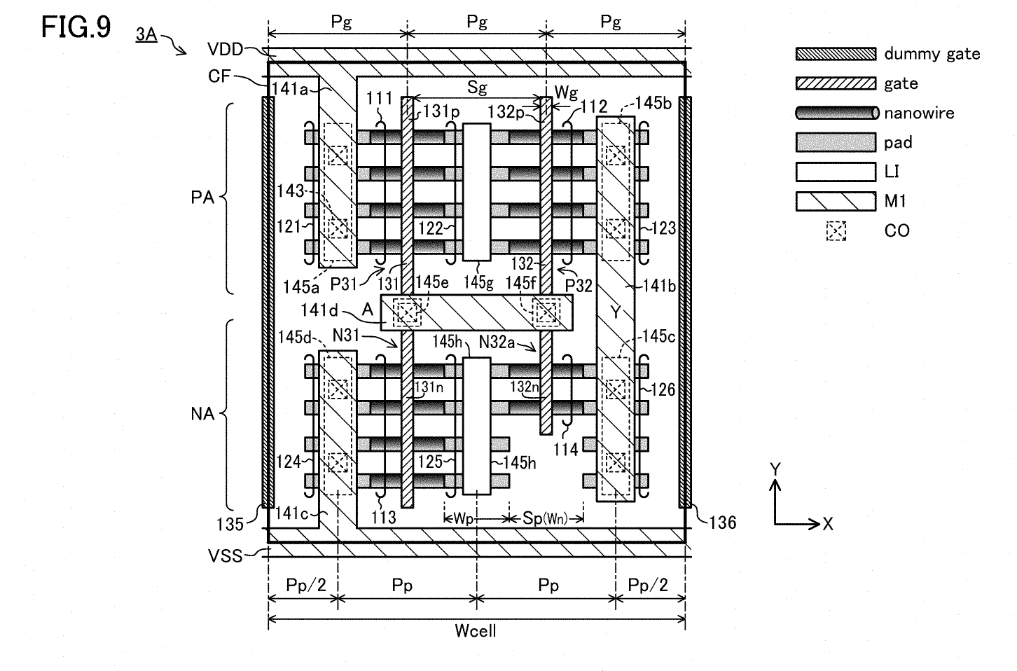

FIG. 9 shows another example of the standard cell in the present embodiment. The layout configuration of this standard cell 3A of FIG. 9 is basically similar to that of FIG. 7. Common components are denoted by the same reference characters, and a detailed description thereof may be omitted here. In FIG. 9, the number of the nanowires 113 of the nanowire FET N31 is different from that of the nanowires 114 of the nanowire FET N32a, where the nanowire FETs N31 and N32a constitute a serial portion N3, and the same input is given to the nanowire FETs N31 and N32a.

In accordance with the configuration of FIG. 7 described above, the number of the nanowires 113 of the nanowire FET N31 and the number of the nanowires 114 of the nanowire FET N32 are each eight, i.e., equal to each other. Consequently, the driving capability of the serial portion N3 is set to be about 0.5 times the driving capability of the nanowire FET N31. Similarly, the number of the nanowires 111 of the nanowire FET P31 and the number of the nanowires 112 of the nanowire FET P32 are each eight, i.e., equal to each other, and the driving capability of the serial portion P3 is set to be about 0.5 times the driving capability of the nanowire FET P31.

In the configuration of FIG. 9, the nanowire FET N31 includes eight (four in the Y direction and two in the vertical direction) parallelly arranged nanowires 113 extending in the X direction, and the nanowire FET N32a includes four (two in the Y direction and two in the vertical direction) parallelly arranged nanowires 114 extending in the X direction. Consequently, in accordance with the configuration of FIG. 9, the driving capability of the serial portion N3 is set to be within a range of 0.25 to 0.5 times the driving capability of the nanowire FET N31.

As can be seen, in the configuration of FIG. 9, in the serial portion N3, the number of the nanowires 113 forming part of the nanowire FET N31 and the number of the nanowires 114 forming part of the nanowire FET N32a are made different from each other. Thus, if a plurality of nanowire FETs which are connected in series and to which the same input is given include different numbers of nanowires, the driving capability can be finely adjusted.

Although FIG. 9 illustrates an example in which in the serial portion N3, the nanowire FETs include different numbers of nanowires, the number of the nanowires 111 forming part of the nanowire FET P31 and the number of the nanowires 112 forming part of the nanowire FET P32 may be made different from each other in the serial portion P3, in addition to the configuration of FIG. 9 or in place of the modification from the configuration of FIG. 7 to the configuration of FIG. 9. With this configuration, the driving capability of the serial portion P3 can be finely adjusted.

Also in the configuration of FIG. 9, the number of the nanowire FETs constituting the serial portion, i.e., the nanowire FETs which are connected in series and to which the same input is given may be three or more, and some or all of these nanowire FETs connected in series may include different numbers of nanowires. In other words, in accordance with driving capability required for each of the serial portions N3 and P3, the number of the nanowire FETs constituting the serial portion and the number of the nanowires constituting each of the nanowire FETs can each be set to be any number.

### Another Example 2

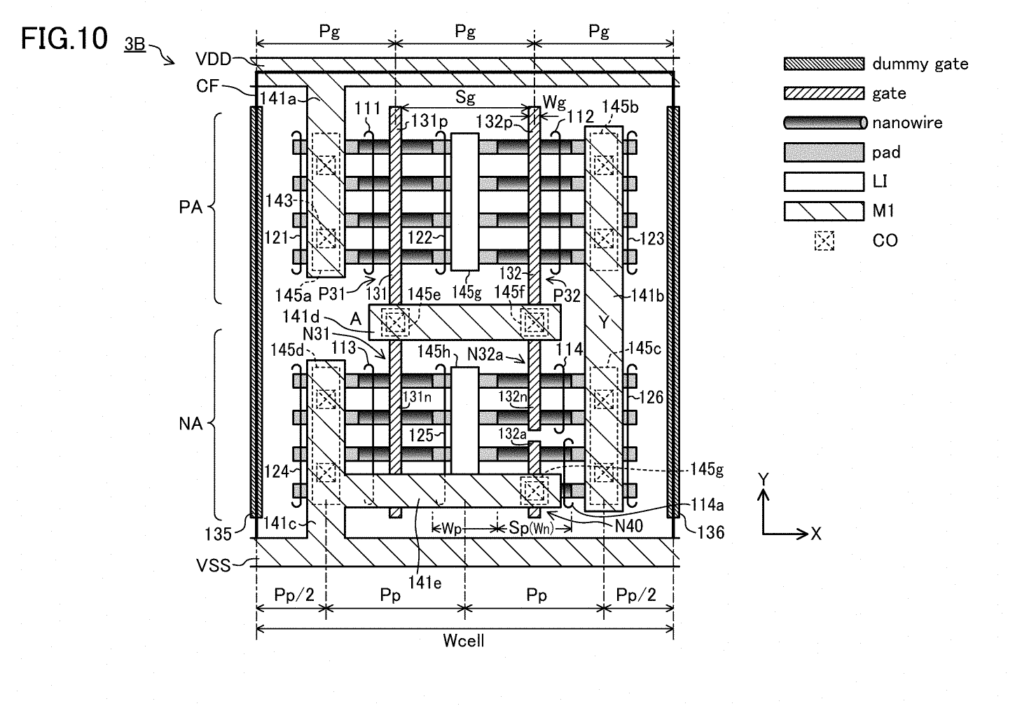

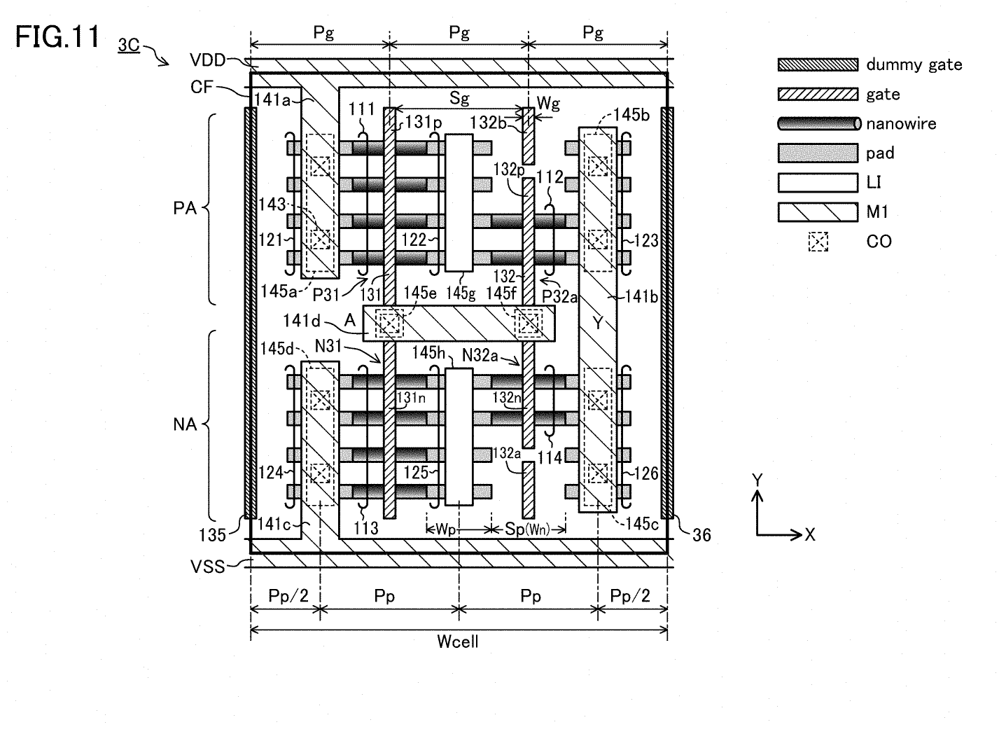

FIG. 10 shows another example of the standard cell in the present embodiment. The layout configuration of this standard cell 3B of FIG. 10 is basically similar to that of each of FIGS. 7 and 9. Common components are denoted by the same reference characters, and a detailed description thereof may be omitted here. The standard cell 3B of FIG. 10 is provided with an n-type nanowire FET N40 as a dummy transistor having no contribution to a logical operation of a circuit.

The nanowire FET N40 includes dummy nanowires 114a and a dummy gate electrode 132a. The dummy nanowires 114a are provided between the group of the pads 125 and the group of the pads 126 so as to extend in the X direction in parallel with the nanowires 114. The dummy gate electrode 132a surrounds peripheries of the dummy nanowires 114a within predetermined ranges of the dummy nanowires 114a in the X direction. Further, the dummy gate electrode 132a is connected to the interconnect VSS through the interconnect 141c, an interconnect 141e extending in the X direction from an intermediate portion of the interconnect 141c in the Y direction, and the local interconnect 145g. That is to say, a gate of the nanowire FET N40 is fixed to a ground potential.

The configuration of the standard cell 3B is obtained by modifying the configuration of the standard cell 3 (refer to FIG. 7) such that the gate electrode 132n of the nanowire FET N32 is divided into two gate electrodes. The upper one of these two gate electrodes in the drawing is used as the gate electrode 132n of the nanowire FET N32a, whereas the lower one of these two gate electrodes in the drawing is used as the dummy gate electrode 132a, which is fixed to a ground potential. That is to say, the dummy gate electrode 132a is arranged in the same straight line as, and on the lower side in the Y direction of, the gate electrode 132n of the nanowire FET N32a, and is arranged separately from the gate electrode 132n.

In accordance with the configuration of FIG. 10, for the nanowire FETs N31 and N32a arranged adjacent to each other on the same straight line in the X direction and including different numbers of nanowires, providing the nanowire FET N40 as a dummy transistor allows the groups of pads 124, 125, 126 to have respective upper ends having the same position in the Y direction, and respective lower ends having the same position in the Y direction. Consequently, the semiconductor integrated circuit device is easily manufactured, and process-induced variations therein can be reduced, thus improving yield.

Although, in the configuration of FIG. 10, the pads 124, 125, 126 have respective upper ends having the same position in the Y direction, and respective lower ends having the same position in the Y direction, only either the upper or lower ends may have the same position, or neither of them may have the same position.

### Another Example 3

FIG. 11 shows another example of the standard cell in the present embodiment. The layout configuration of this standard cell 3C of FIG. 11 is basically similar to that of the standard cell 3A of FIG. 9. Common components are denoted by the same reference characters, and a detailed description thereof may be omitted here. In FIG. 11, the number of the nanowires 111 of the nanowire FET P31 is different from that of the nanowires 112 of the nanowire FET P32a, where the nanowire FETs P31 and P32a constitute a serial portion P3.

In the layout configuration of FIG. 11, the nanowire FET P31 includes eight (four in the Y direction and two in the vertical direction) parallelly arranged nanowires 111 extending in the X direction, and the nanowire FET P32a includes four (two in the Y direction and two in the vertical direction) parallelly arranged nanowires 112 extending in the X direction. Consequently, in accordance with the configuration of FIG. 11, the driving capability of the serial portion P3 constituted by the nanowire FETs P31 and P32a is set to be within a range of 0.25 to 0.5 times the driving capability of the nanowire FET P31.

In the layout configuration of FIG. 11, in the nanowire FET P32a, the arrangement range of the nanowires 112 is localized relative to the arrangement range of the pads 122 and 123 in the Y direction. Specifically, in FIG. 11, the nanowires 112 are localized on the lower side of the arrangement range of the pads 122, 123 in the Y direction, and the two nanowires 112 are aligned in the X direction with two lower ones of the nanowires 111 of the nanowire FET P31 in the drawing.

As in FIG. 9, in the nanowire FET N32a, the arrangement range of the nanowires 114 is localized relative to the arrangement range of the pads 125 and 126 in the Y direction. Specifically, in FIG. 11, the nanowires 114 are localized on the upper side of the arrangement range of the pads 125, 126 in the Y direction, and the two nanowires 114 are aligned in the X direction with two upper ones of the nanowires 113 of the nanowire FET N31.

Further, the nanowire FET P32a includes a dummy gate electrode 132b. The dummy gate electrode 132b is disposed between the group of the pads 122 and the group of the pads 123 so as to be aligned with the gate electrode 132p. The dummy gate electrode 132b is separated from the gate electrode 132p. Similarly, the nanowire FET N32a includes a dummy gate electrode 132a. The dummy gate electrode 132a is disposed between the group of the pads 125 and the group of the pads 126 so as to be as aligned with the gate electrode 132n. The dummy gate electrode 132a is separated from the gate electrode 132n.

In accordance with the configuration of FIG. 11, providing the dummy gate electrodes 132a and 132b allows, in the standard cell 3C, the gate lines of the nanowire FETs arranged adjacent to each other on the same straight line in the X direction and including different numbers of nanowires to have respective upper ends aligned in the X direction, and respective lower ends aligned in the X direction. With this configuration, the semiconductor integrated circuit device is easily manufactured, and process-induced variations therein can be reduced, thus improving yield.

In the layout configuration of FIG. 11, the dummy gate electrodes 132a and 132b are not necessarily provided, or only either one of them may be provided.

Although, in the configuration of FIG. 11, the nanowire FETs P31 and N31 each include eight nanowires, and the nanowire FETs P32a and N32a each include four nanowires, this is a non-limiting example. The p-type nanowire FET and the n-type nanowire FET may include different numbers of nanowires.

Although, in the configuration of FIG. 11, the nanowires 112 of the nanowire FET P32a are each aligned with an associated one of the nanowires 111 of the nanowire FET P31 in the X direction, they are not necessarily aligned with each other. Although the nanowires 114 of the nanowire FET N32a are each aligned with an associated one of the nanowires 113 of the nanowire FET N31 in the X direction, they are not necessarily aligned with each other.

### Another Example 4

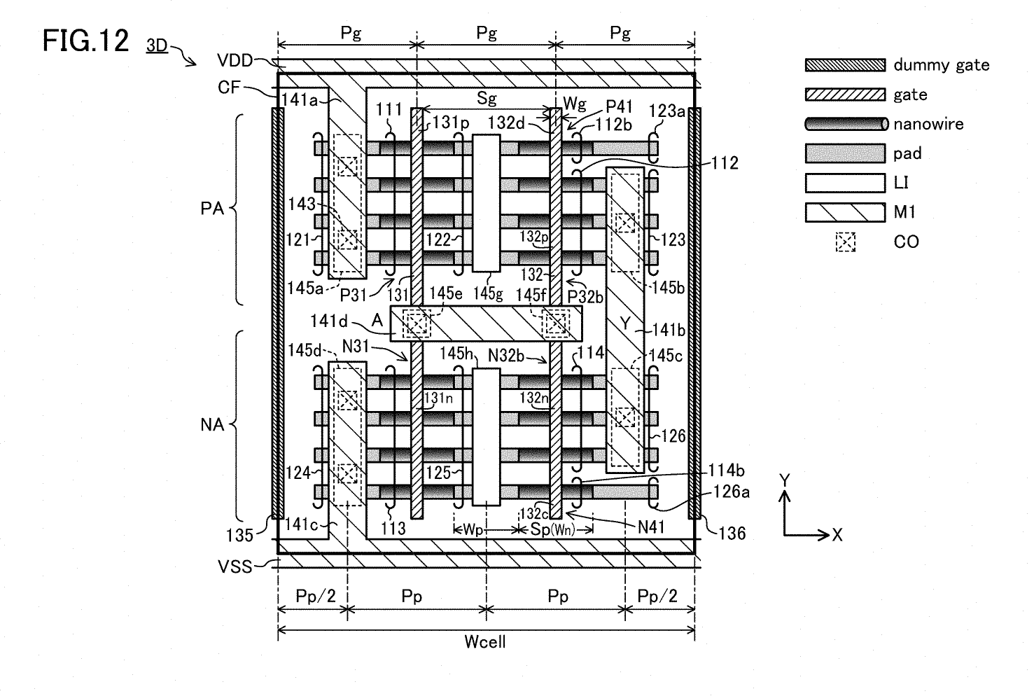

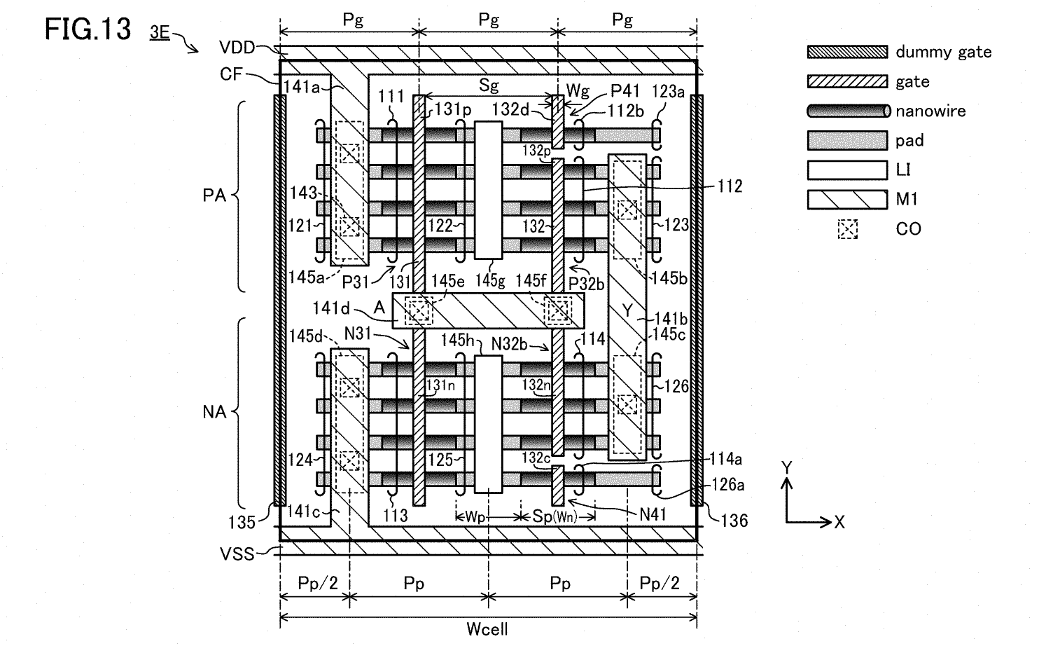

FIG. 12 shows another example of the standard cell in the present embodiment. The layout configuration of this standard cell 3D of FIG. 12 is basically similar to that of FIG. 7. Common components are denoted by the same reference characters, and a detailed description thereof may be omitted here. In FIG. 12, a p-type nanowire FET P41 and an n-type nanowire FET N41 as dummy transistors having no contribution to a logical operation of the circuit are provided.

In the configuration of FIG. 12, nanowire FETs P32b and N32b each include six (three in the Y direction and two in the vertical direction) parallelly arranged nanowires 112, 114 extending in the X direction. With this configuration, the driving capability of the serial portion P3 including the nanowire FETs P31 and P32b is set to be within a range of 0.25 to 0.5 times the driving capability of the nanowire FET P31, and is set to be different from that of the configurations shown in FIGS. 1 to 11. Similarly, the driving capability of the serial portion N3 including the nanowire FETs N31 and N32b is set to be within a range of 0.25 to 0.5 times the driving capability of the nanowire FET N31, and is set to be different from that of the configurations shown in FIGS. 1 to 11.

The nanowire FET P41 includes a group of dummy nanowires 112b and a dummy pad 123a. The dummy pad 123a is disposed adjacent to the upper side of the group of pads 123 in the Y direction. The group of dummy nanowires 112b includes two (one in the Y direction and two in the vertical direction) nanowires arranged between the group of the pads 122 and the dummy pad 123a in parallel with the nanowires 112 to extend in the X direction. The gate line 132 extends so as to cross the arrangement position of the dummy nanowire 112b in the Y direction and surrounds peripheries of the dummy nanowires 112b. That is to say, a dummy gate electrode 132d of the nanowire FET P41 is formed integrally with the gate electrode 132p of the nanowire FET P32b.

The nanowire FET N41 includes a group of dummy nanowires 114b and a dummy pad 126a. The dummy pad 126a is disposed adjacent to the lower side of the group of pads 126 in the Y direction. The group of dummy nanowires 114b includes two (one in the Y direction and two in the vertical direction) nanowires arranged between the group of the pads 125 and the dummy pad 126a in parallel with the nanowires 114 to extend in the X direction. The gate line 132 extends so as to cross the arrangement position of the dummy nanowires 114b in the Y direction and surrounds peripheries of the dummy nanowires 114b. That is to say, a dummy gate electrode 132c of the nanowire FET N41 is formed integrally with the gate electrode 132n of the nanowire FET N32b.

That is to say, the configuration of the standard cell 3D is obtained by modifying the configuration of the standard cell 3 (refer to FIG. 7) such that the pads 123 are classified under two groups in the nanowire FET P32, and the pads 126 are classified under two groups in the nanowire FET N32.

In accordance with the configuration of FIG. 12, for the nanowire FETs P31 and P32b arranged adjacent to each other in the same straight line in the X direction and including different numbers of nanowires, providing the nanowire FET P41 as a dummy transistor allows the groups of the pads 121, 122 of the nanowire FET P31 to each have an upper end having the same position as that of a region surrounding the pads 123 of the nanowire FET P32b and the pad 123a in the Y direction, and a lower end having the same position as that of this region in the Y direction. Similarly, for the nanowire FETs N31 and N32b arranged adjacent to each other in the same straight line in the X direction and including different numbers of nanowires, providing the nanowire FET N41 as a dummy transistor allows the groups of pads 124, 125 of the nanowire FET N31 to each have an upper end having the same position as that of a region surrounding the pads 126 of the nanowire FET N32b and the pad 126a in the Y direction, and a lower end having the same position as that of this region in the Y direction. Consequently, the semiconductor integrated circuit device is easily manufactured, and process-induced variations therein can be reduced, thus improving yield.

### Another Example 5

FIG. 13 shows another example of the standard cell in the present embodiment. The layout configuration of this standard cell 3E of FIG. 13 is basically similar to that of the standard cell 3D of FIG. 12. Common components are denoted by the same reference characters, and a detailed description thereof may be omitted here. In FIG. 13, the nanowire FETs P41 and N41 as dummy transistors having no contribution to a logical operation of the circuit each include a dummy gate electrode separated from the gate line 132.

That is to say, the nanowire FET P41 includes a group of dummy nanowires 112b and a dummy pad 123a. A dummy gate electrode 132d is aligned with the gate line 132, and surrounds peripheries of the dummy nanowires 112b. The dummy gate electrode 132d is separated from the gate electrode 132p of the nanowire FET P32b. The nanowire FET N41 includes a group of dummy nanowires 114a and a dummy pad 126a. A dummy gate electrode 132c is aligned with the gate line 132, and surrounds peripheries of the dummy nanowires 114a. The dummy gate electrode 132c is separated from the gate electrode 132n of the nanowire FET N32b.

Also in the embodiment shown in FIG. 13, just like the embodiment shown in FIG. 12, the groups of pads 121, 122 can each have an upper end having the same position as that of the region surrounding the pads 123 and 123a, and a lower end having the same position as that of this region. Similarly, the groups of pads 124, 125 can each have an upper end having the same position as that of the region surrounding the pads 126 and 126a, and a lower end having the same position as that of this region. Consequently, the semiconductor integrated circuit device is easily manufactured, and process-induced variations therein can be reduced, thus improving yield.

### Another Example 6

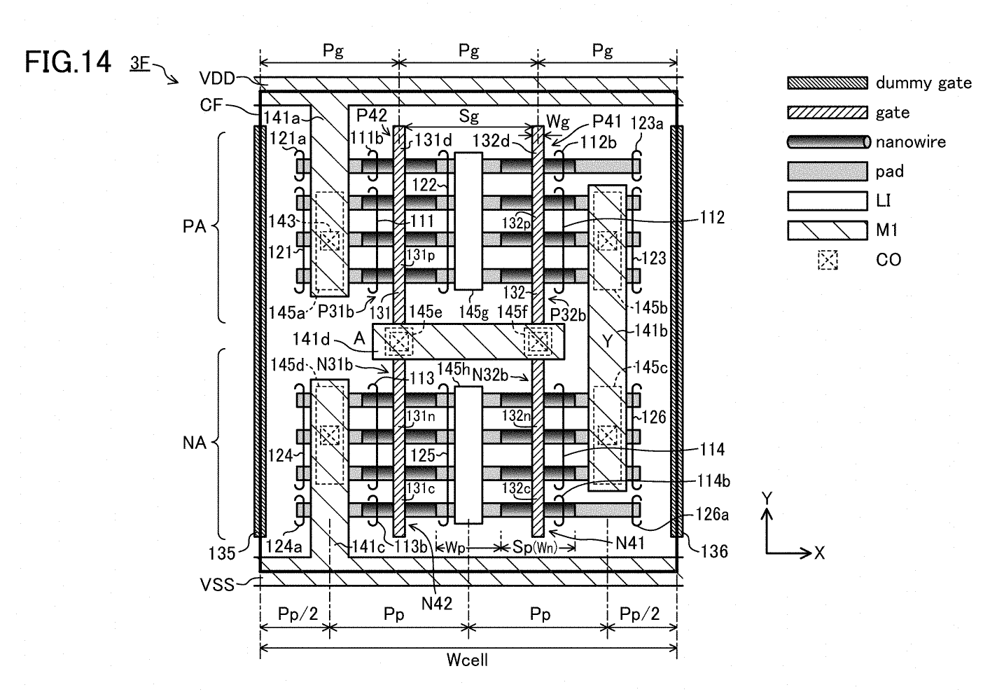

FIG. 14 shows another example of the standard cell in the present embodiment. The layout configuration of this standard cell 3F of FIG. 14 is basically similar to the standard cell 3D of FIG. 12. Common components are denoted by the same reference characters, and a detailed description thereof may be omitted here. In FIG. 14, in addition to the nanowire FETs P41 and N41, a p-type nanowire transistor P42 and an n-type nanowire transistor N42 as dummy transistors having no contribution to a logical operation of the circuit are provided.

In FIG. 14, nanowire FETs P31b and N31b each include six (three in the Y direction and two in the vertical direction) parallelly arranged nanowires 111, 113 extending in the X direction. With this configuration, in FIG. 14, the driving capability of the serial portion P3 including the nanowire FETs P31b and P32b is set to be within a range of 0.25 to 0.5 times the driving capability of the nanowire FET P31 shown in FIG. 7, and is set to be different from that of the configurations shown in FIGS. 1 to 13. Similarly, the driving capability of the serial portion N3 including the nanowire FETs N31b and N32b is set to be within a range of 0.25 to 0.5 times the driving capability of the nanowire FET N31 shown in FIG. 7, and is set to be different from that of the configurations shown in FIGS. 1 to 13.

The nanowire FET P42 includes a group of dummy nanowires 111b and a dummy pad 121a. The dummy pad 121a is disposed adjacent to the upper side of the group of pads 121 in the Y direction. The group of dummy nanowires 111b includes two (one in the Y direction and two in the vertical direction) nanowires arranged between the dummy pad 121a and the group of pads 122 in parallel with the nanowires 111 to extend in the X direction. The gate line 131 extends so as to cross the arrangement position of the dummy nanowires 111b in the Y direction, and surrounds peripheries of the dummy nanowires 111b. That is to say, a dummy gate electrode 131d of the nanowire FET P42 is formed integrally with the gate electrode 131p of the nanowire FET P31b.

The nanowire FET N42 includes a group of dummy nanowires 113b and a dummy pad 124a. The dummy pad 124a is disposed adjacent to the lower side of the group of pads 124 in the Y direction. The group of dummy nanowires 113b includes two (one in the Y direction and two in the vertical direction) nanowires arranged between the dummy pad 124a and the group of pads 125 in parallel with the nanowires 113 to extend in the X direction. The gate line 131 extends so as to cross the arrangement position of the dummy nanowires 113b in the Y direction, and surrounds peripheries of the dummy nanowires 113b. That is to say, a dummy gate electrode 131c of the nanowire FET N42 is formed integrally with the gate electrode 131n of the nanowire FET N31b.

That is to say, the configuration of the standard cell 3F is obtained by modifying the configuration of the standard cell 3D of FIG. 12 such that the pad 121 are classified under two groups in the nanowire FET P31, and the pads 124 are classified under two groups in the nanowire FET N31.

In accordance with the configuration of FIG. 14, for the nanowire FETs P31b and P32b each including six nanowires, providing the nanowire FETs P41 and P42 as dummy transistors allows respective upper ends of a region surrounding the pads 121, 121a, the group of pads 122, and a region surrounding the pads 123, 123a to have the same position in the Y direction, and allows respective lower ends thereof to have the same position in the Y direction. Further, when a standard cell such as the cell shown in any one of FIGS. 1 to 13 is adjacent to the standard cell of FIG. 14 in the X direction, and these standard cells have the same height in the Y direction, the pads arranged in the p-type transistor region PA can have their upper ends having the same position, and have their lower ends having the same position. Similarly, for the nanowire FETs N31b and N32b each including six nanowires, providing the nanowire FETs N41 and N42 as dummy transistors allows respective upper ends of a region surrounding the pads 124, 124a, the group of pads 125, and a region surrounding the pads 126, 126a to have the same position in the Y direction, and allows respective lower ends thereof to have the same position in the Y direction. Further, when a standard cell such as the cell shown in any one of FIGS. 1 to 13 is adjacent to the standard cell of FIG. 14 in the X direction, and these standard cells have the same height in the Y direction, the pads arranged in the n-type transistor region NA can have their upper ends having the same position, and have their lower ends having the same position. Consequently, the semiconductor integrated circuit device is easily manufactured, and process-induced variations therein can be reduced, thus improving yield.

Although, in the embodiment of FIG. 14, the nanowire FETs P41, P42, N41, and N42 as dummy transistors each include one nanowire in the Y direction, this is a non-limiting example, and two or more nanowires may be provided in the Y direction. Although the p-type region and the n-type region are horizontally symmetric to each other, this is a non-limiting example. For example, only the p-type region may include a nanowire FET as a dummy transistor, or the manner of separation of pads, the number of nanowires, or any other feature may vary between the p-type region and the n-type region.

Although, in the layout configurations shown in the present disclosure, the intervals in the Y direction and thicknesses of the nanowires are illustrated to be equal, they are not necessarily equal. The number of the nanowires of each of the nanowire FETs shown in the present disclosure is only by way of example, and is a non-limiting example.

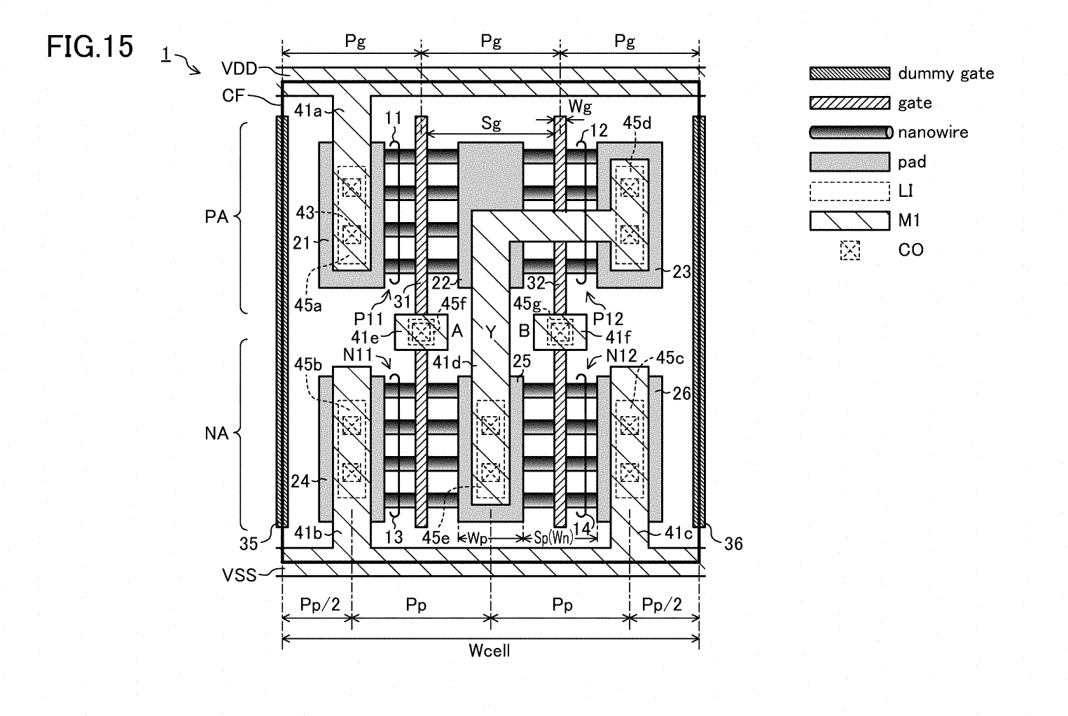

In the foregoing description, in the nanowire FET, the pads are separated from the nanowires arranged in the Y direction. However, pads may be integrated with the nanowires arranged in the Y direction. FIG. 15 shows a variation of the layout configuration of FIG. 1. In FIG. 15, the pads 21, 22, 23, 24, 25, 26 are each integrated with associated ones of the groups of nanowires 11, 12, 13, 14 each including four nanowires arranged in the Y direction.

Although the present disclosure describes the standard cells constituting a NOR gate, a NAND gate, and an inverter, the present disclosure may be directed to a standard cell for other logical circuits having a serial portion including nanowire FETs connected in series. This also provides similar advantages.

The present disclosure provides a layout configuration of a semiconductor integrated circuit device including a nanowire FET, the layout configuration being effective for making manufacturing the device easy, and is useful for improving performance of the semiconductor integrated circuit device.

What is claimed is:

1. A semiconductor integrated circuit, comprising:
a standard cell including first and second transistors that are nanowire field effect transistors (FETs), the first and second transistors being connected in series through a connection node used only for mutual connection, wherein
the first and second transistors include:
a first pad;
Na (Na is an integer of one or more) first nanowires each having a first end that is connected to the first pad, each extending in a first direction from the first end, and each having a lower surface above a lower surface of the first pad;
a first gate electrode surrounding peripheries of the first nanowires within predetermined ranges of the first nanowires in the first direction;
a second pad connected to second ends of the first nanowires;
Nb (Nb is an integer of one or more) second nanowires each having a first end that is connected to the second pad, each extending in the first direction from the first end, and each having a lower surface above a lower surface of the second pad;
a second gate electrode surrounding peripheries of the second nanowires within predetermined ranges of the second nanowires in the first direction; and
a third pad connected to second ends of the second nanowires.

2. The semiconductor integrated circuit of claim 1, wherein in the standard cell, the first and second nanowires have the same length in the first direction.

3. The semiconductor integrated circuit of claim 1, wherein
the first and second transistors are transistors of the same conductive type, and
a same signal is input to gates of the first and second transistors.

4. The semiconductor integrated circuit of claim 1, wherein
the standard cell is a NAND gate or a NOR gate, and
the first and second transistors constitute a serial portion of the NAND gate or the NOR gate.

5. The semiconductor integrated circuit of claim 1, wherein
the number (Na) of the first nanowires is greater than the number (Nb) of the second nanowires.

6. The semiconductor integrated circuit of claim 5, further comprising:
a dummy gate electrode aligned with the second gate electrode while being separated from the second gate electrode.

7. The semiconductor integrated circuit of claim 6, wherein
the second gate electrode is shorter than the first gate electrode.

8. The semiconductor integrated circuit of claim 5, wherein
the standard cell includes a third transistor that is a dummy nanowire FET having no contribution to a logical operation of a circuit, and
the third transistor includes:
a dummy nanowire provided between the second pad and the third pad and extending in the first direction; and
a dummy gate electrode aligned with the second gate electrode while being separated from the second gate electrode, and surrounding a periphery of the dummy nanowire within a predetermined range of the dummy nanowire in the first direction.

9. The semiconductor integrated circuit of claim 5, wherein
the standard cell includes a third transistor that is a dummy nanowire FET having no contribution to a logical operation of a circuit, and
the third transistor includes:
a dummy nanowire provided so as to extend in the first direction in parallel with the second nanowires; and
a dummy pad arranged together with the third pad, and separated from the third pad, in a second direction perpendicular to the first direction, having a lower surface below a lower surface of the dummy nanowire, and connected to the dummy nanowire.

10. The semiconductor integrated circuit of claim 9, further comprising:
a dummy gate electrode aligned with the second gate electrode while being separated from the second gate electrode, and surrounding a periphery of the dummy nanowire within a predetermined range of the dummy nanowire in the first direction.

11. A semiconductor integrated circuit, comprising:
a standard cell including first and second transistors that are nanowire field effect transistors (FETs),
wherein
the first and second transistors include:
a first pad;
Na (Na is an integer of one or more) first nanowires each having a first end that is connected to the first pad, each extending in a first direction from the first end, and each having a lower surface above a lower surface of the first pad;
a first gate electrode surrounding peripheries of the first nanowires within predetermined ranges of the first nanowires in the first direction;
a second pad connected to second ends of the first nanowires;
Nb (Nb is an integer of one or more) second nanowires each having a first end that is connected to the second pad, each extending in the first direction from the first end, and each having a lower surface above a lower surface of the second pad;
a second gate electrode surrounding peripheries of the second nanowires within predetermined ranges of the second nanowires in the first direction; and
a third pad connected to second ends of the second nanowires, and
the second pad is not connected to any interconnect other than the first and second nanowires.

12. The semiconductor integrated circuit of claim 11, wherein
in the standard cell, the first and second nanowires have the same length in the first direction.

13. The semiconductor integrated circuit of claim 11, wherein
the first and second transistors are transistors of the same conductive type, and
a same signal is input to gates of the first and second transistors.

14. The semiconductor integrated circuit of claim 11, wherein
the standard cell is a NAND gate or a NOR gate, and
the first and second transistors constitute a serial portion of the NAND gate or the NOR gate.

15. The semiconductor integrated circuit of claim 11, wherein
the number (Na) of the first nanowires is greater than the number (Nb) of the second nanowires.

16. A semiconductor integrated circuit, comprising:
a standard cell that is a NAND gate or a NOR gate having a serial portion including M (M is an integer of two or more) nanowire field effect transistors (FETs),
wherein
the M nanowire FETs include:
M+1 pads arranged at a predetermined pitch in a first direction;
M groups of nanowires each including L (L is an integer of 1 or more) nanowires that are each provided between adjacent ones of the pads, extend in the first direction to connect the adjacent ones of the pads together, and each have a lower surface above lower surfaces of the pads; and
M gate electrodes surrounding peripheries of the associated nanowires within predetermined ranges of the associated nanowires in the first direction.

17. The semiconductor integrated circuit of claim 16, wherein
the M nanowires have the same length in the first direction.
